(19) United States
(12) Patent Application Publication
(10) Pub. No.: US 2009/0256598 A1
(43) Pub. Date: Oct. 15, 2009

(54) POWER-UP SIGNAL GENERATOR OF SEMICONDUCTOR MEMORY APPARATUS AND METHOD FOR CONTROLLING THE SAME

(75) Inventor: Yong Hoon Kim, Ichon (KR)

Correspondence Address: BAKER & MCKENZIE LLP;PATENT DEPARTMENT, 2001 ROSS AVENUE, SUITE 2300, DALLAS, TX, 75201, US

(73) Assignee: HYNIX SEMICONDUCTOR INC., Ichon (KR)

(21) Appl. No.: 12/345,761

(22) Filed: Dec. 30, 2008

(30) Foreign Application Priority Data
Apr. 10, 2008 (KR) 10-2008-0033316

(51) Int. Cl. H03K 17/22

(52) U.S. Cl. 327/143

(57) ABSTRACT

A power-up signal generator of a semiconductor memory apparatus includes a power-up signal generating unit that includes a MOS transistor having a gate receiving a divided voltage of an external supply voltage, the power-up signal generating unit determining a level of a power-up signal according to a turn-ON state of the MOS transistor, and a bulk bias voltage generating unit that applies a bulk bias voltage to a bulk of the MOS transistor to adjust a threshold voltage of the MOS transistor, wherein the bulk bias voltage varies according to a temperature of the semiconductor memory device.

### CROSS-REFERENCES TO RELATED APPLICATION

The present application claims priority under 35 U.S.C. §119(a) to Korean application number 10-2008-0033316, filed on Apr. 10, 2008, in the Korean Intellectual Property Office, which is incorporated by reference in its entirety as if set forth in full.

### BACKGROUND

1. Technical Field

The embodiments described herein relate to a semiconductor memory apparatus and, more particularly, to a power-up signal generator of a semiconductor memory apparatus and a method for controlling the same.

2. Related Art

In general, a semiconductor memory apparatus commonly includes various logic devices and an internal power generating block to ensure stable operation of the semiconductor memory apparatus. Circuits for the logic devices include nodes that are initially set to an undesired level due to an unstable state when an external supply voltage is supplied, wherein logic level failures may occur. Accordingly, the logic devices of a semiconductor memory apparatus must be initialized to a specific value before the logic devices can be operated using the supplied power.

In addition, internal power is applied as a bias to a power terminal of the internal logic devices of the memory apparatus. If the internal power does not have a stable voltage level when the external supply voltage VDD is applied, problems, such as latch-up, occur, whereby the reliability of the memory apparatus may be uncertain. Accordingly, the memory apparatus is provided with an internal power-up circuit in order to initialize the internal logic devices of the memory apparatus and to prevent latch-up caused from the instability of the internal power.

Upon the initial operation of the memory apparatus, the power-up circuit allows the internal logic devices of the memory apparatus to operate after the external supply voltage VDD exceeds a critical level, instead of immediately operating in response to the external supply voltage VDD. Based upon the level of the external supply voltage VDD, the power-up signal, which is an output signal of the power-up circuit, is maintained at a logic low state when the external voltage VDD is lower than a critical level, and is transitioned to a logic high state when the external voltage VDD is stabilized above the critical level.

Generally, when the power-up signal is at a logic low state after the external supply voltage VDD is applied, latches embedded within the internal logic devices of the memory apparatus are initialized as a preset value. At this time, an internal power generating block is initialized.

FIG. 1 is a schematic circuit diagram of a conventional power-up signal generator. Referring to FIG. 1, the power-signal generator 10 supplies a gate voltage VG by dividing an external supply voltage VDD using resistors R1 and R2, and determines the turn-ON of an NMOS transistor N1 in response to the gate voltage VG. After a voltage V is continuously raised through a PMOS transistor P1 and a resistor R3, the voltage V is dropped if the NMOS transistor N1 is turned ON, so that a power-up signal ‘Pwrup’ is output.

FIG. 2 is a graphical representation of an operation of the conventional power-up signal generator of FIG. 1. In FIG. 2, the level of the gate voltage VG and a voltage level of the power-up signal ‘Pwrup’ according to the level variation of the external supply voltage VDD is shown, wherein the X-axis and Y-axis represent the external supply voltage VDD and the voltage V, respectively. As the external supply voltage VDD is increased, the level of the gate voltage VG increases at a predetermined rate. If the level of the gate voltage VG exceeds a predetermined level, then the voltage V is activated, and the power-up signal ‘Pwrup’, which is obtained by buffering the voltage V through first and second inverters INV1 and INV2, is activated. However, the conventional power-up signal generator is sensitively affected by an ambient temperature of the circuit.

FIG. 3 is a graph representation of an operation of a power-up signal of the conventional power-up signal generator of FIG. 1. In FIG. 3, the power-up signal ‘Pwrup’ (of FIG. 1) is provided according to an ambient temperature of a apparatus. “Hot” represents the power-up signal ‘Pwrup’ when the ambient temperature is relatively high (about 90° C. or more), and “Cold” represents the power-up signal ‘Pwrup’ when the ambient temperature is relatively low (about −10° C. or less).

Referring to FIGS. 1 and 3, the power-up signal ‘Pwrup’ is activated at a lower level of the external supply voltage VDD according to the increase of the ambient temperature, and activated at a higher level of the external supply VDD according to the decrease of the ambient temperature. This is because a threshold voltage Vth of a MOS transistor is reduced as the ambient temperature increases. If the ambient temperature is increased, then the threshold voltage Vth is reduced, so the power-up signal ‘Pwrup’ is activated when the external supply voltage VDD is lower than a reference level. Accordingly, initialization of the memory apparatus fails. In addition, if the ambient temperature is lowered, the threshold voltage Vth increases so that the power-up signal ‘Pwrup’ is activated when the external voltage VDD is higher than the reference level. Accordingly, an erroneous operation may occur in a low-voltage region of the memory apparatus.

The above phenomenon may occur even when manufacturing processes for fabricating the memory apparatus is changed. If the power-up level variation according to the temperature variation is greatly increased, as described above, logic failure may occur, so that the operational reliability of the memory apparatus will be degraded, and operational yield of the memory apparatus will be reduced.

### SUMMARY

A power-up signal generator of a semiconductor memory apparatus and a method for controlling a power-up signal generator of a semiconductor memory apparatus capable of improving operational reliability is described herein.

In one aspect, a power-up signal generator of a semiconductor memory apparatus includes a power-up signal generating unit that includes a MOS transistor having a gate receiving a divided voltage of an external supply voltage, the power-up signal generating unit determining a level of a power-up signal according to a turn-ON state of the MOS transistor, and a bulk bias voltage generating unit that applies a bulk bias voltage to a bulk of the MOS transistor to adjust a threshold voltage of the MOS transistor, wherein the bulk bias voltage varies according to a temperature of the semiconductor memory apparatus.

In another aspect, a method for controlling a power-up signal generator of a semiconductor memory apparatus includes determining a level of a power-up signal from a power-up signal generator according to a turn-ON state of a MOS transistor of a power-up signal generating unit, and applying a variable bulk bias voltage from a bulk bias voltage generating unit to a bulk of the MOS transistor to adjust a threshold voltage of the MOS transistor according to a temperature of the semiconductor memory apparatus.

These and other features, aspects, and embodiments are described below in the section “Detailed Description.”

### BRIEF DESCRIPTION OF THE DRAWINGS

Features, aspects, and embodiments are described in conjunction with the attached drawings, in which:

FIG. 1 is a schematic circuit diagram of a conventional power-up signal generator;

FIG. 2 is a graphical representation of an operation of the conventional power-up signal generator of FIG. 1;

FIG. 3 is a graph representation of an operation of a power-up signal of the conventional power-up signal generator of FIG. 1;

FIG. 4 is a schematic circuit diagram of an exemplary power-up signal generator according to one embodiment;

FIG. 5 is a graphical representation of exemplary voltage variation characteristics of an exemplary bulk bias voltage generator that can be included in the generator of FIG. 4 according to one embodiment;

FIG. 6 is a graphical representation of an exemplary comparison of a power-up signal of the power-up signal generator of FIG. 4 and the conventional power-up signal generator of FIG. 1 according to one embodiment; and

FIG. 7 is a graphical representation of exemplary voltage variation characteristics of another exemplary bulk bias voltage generator according to another embodiment.

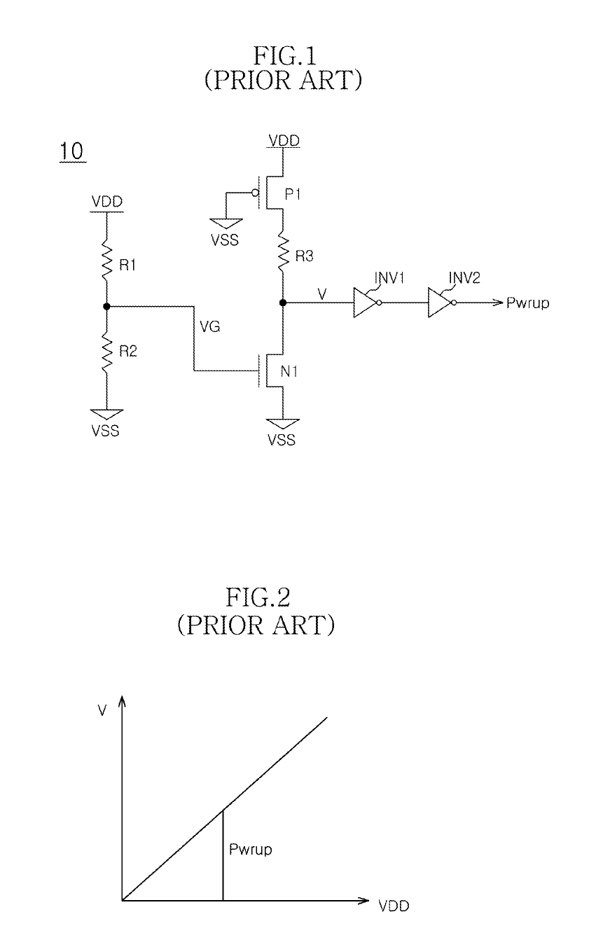

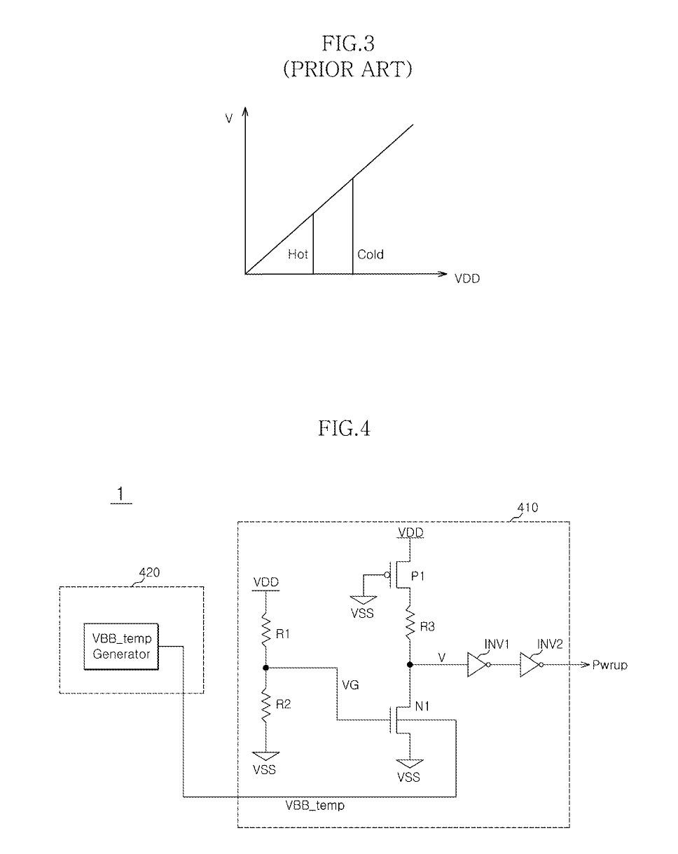

### DETAILED DESCRIPTION

FIG. 4 is a schematic circuit diagram of an exemplary power-up signal generator according to one embodiment. In FIG. 1, a power-up signal generator 1 of a semiconductor memory apparatus can be configured to include a power-up signal generating unit 410 and a bulk bias voltage generator 420. The power-up signal generating unit 410 can function to allow an NMOS transistor N1 to respond to a gate voltage VG and generate a power-up signal ‘Pwrup’. The bulk bias voltage generator 420 can apply a bulk bias voltage (VBB_temp), which varies according to a temperature of the semiconductor memory apparatus, to a bulk of the NMOS transistor N1 provided internally with the power-up signal generating unit 410.

The power-up signal generating unit 410 can determine a level of the power-up signal ‘Pwrup’ according to a turn-ON state of the NMOS transistor N1 that can receive a divided voltage of an external supply voltage VDD as a gate voltage VG. The external supply voltage VDD can raise a level of a voltage V through a PMOS transistor P1 and a resistor R3, and the voltage V can be buffered through first and second inverters INV1 and INV2 such that a level of the power-up signal ‘Pwrup’ is increased. The external supply voltage VDD can be divided by resistors R1 and R2 such that the gate voltage VG is applied to the NMOS transistor N1. Accordingly, if the NMOS transistor N1 is turned ON, then the level of the voltage V can be reduced, so that the level of the power-up signal ‘Pwrup’ can be reduced. The bulk bias voltage generator 420 can generate the bulk bias voltage (VBB_temp) according to varying temperatures by using a temperature compensation detector, for example.

FIG. 5 is a graphical representation of exemplary voltage variation characteristics of an exemplary bulk bias voltage generator of FIG. 4 according to one embodiment. In FIG. 5, after an absolute value of the bulk bias voltage (VBB_temp) is linearly increased from a relatively low temperature of about −40° C. to a relatively high temperature of about 90° C., the absolute value of the bulk bias voltage (VBB_temp) can be constantly maintained at the high temperature of above about 90° C.

If an ambient temperature of the semiconductor memory apparatus increases, then a threshold voltage Vth of the NMOS transistor N1 can be reduced. Accordingly, the reduction of the threshold voltage Vth of the NMOS transistor N1 can be offset using the increase of the threshold Vth derived from application of the low bulk bias voltage (VBB_temp) to the bulk of the NMOS transistor N1, so that the level variation of the power-up signal ‘Pwrup’ according to the temperature variation can be reduced.

Conversely, if the ambient temperature of the semiconductor memory apparatus is reduced, then the threshold voltage Vth of the NMOS transistor N1 can be increased. Accordingly, the increase of the threshold voltage Vth of the NMOS transistor N1 can be offset by using the reduction of the threshold Vth derived from the application of the high bulk bias voltage (VBB_temp) to the bulk of the NMOS transistor N1, so that the level variation of the power-up signal ‘Pwrup’ according to the temperature variation can be reduced.

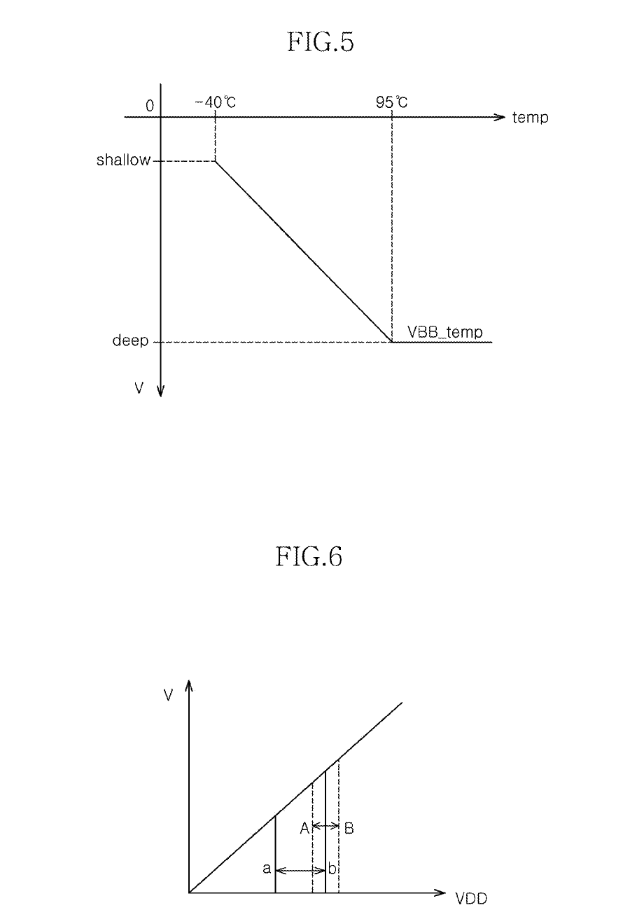

FIG. 6 is a graphical representation of an exemplary comparison of a power-up signal of the power-up signal generator of FIG. 4 and the conventional power-up signal generator of FIG. 1 according to one embodiment. In FIG. 6, reference characters “a” and “b” represent outputs of the power-up signal ‘Pwrup’ at low and high temperatures, respectively, according to the conventional power-up signal generator. Reference characters “A” and “B” represent outputs of the power-up signal ‘Pwrup’ at the low and high temperatures, respectively, in the exemplary power-up signal generator 1 of FIG. 4 equipped with the bulk bias voltage generator 420, which has voltage variation characteristics according to the temperature variations shown in FIG. 5. Since the high bulk bias voltage (VBB_temp) can be applied at a very low temperature according to the temperature characteristics shown in FIG. 5, the reference character “B” represents the level of the power-up signal ‘Pwrup’ being slightly greater than the level of the power-up signal ‘Pwrup’ of “b”. In contrast, since the high bulk bias voltage (VBB_temp) can be applied at the high temperature according to the temperature characteristics shown in FIG. 5, reference character “A” represents the level of the power-up signal ‘Pwrup’ being greater than the level of the power-up signal ‘Pwrup’ of “a”.

For example, since the level increase of the power-up signal ‘Pwrup’ between the reference characters “a” and “A” is greater than the level increase of the power-up signal ‘Pwrup’ between the reference characters “b” and “B”, the level variation of the power-up signal ‘Pwrup’ according to the temperature skew between high and low temperatures can be reduced. Thus, according to one embodiment, the variation of the threshold voltage Vth of the NMOS transistor N1 provided in the power-up signal ‘Pwrup’ generating unit 410 can be compensated due to the application of the variable bulk bias voltage (VBB_temp).

In order to more reduce the level variation of the power-up signal ‘Pwrup’ according to temperature variation, voltage variation characteristics according to a temperature variation of the bulk bias voltage generator 420 can be different from that shown in FIG. 5.

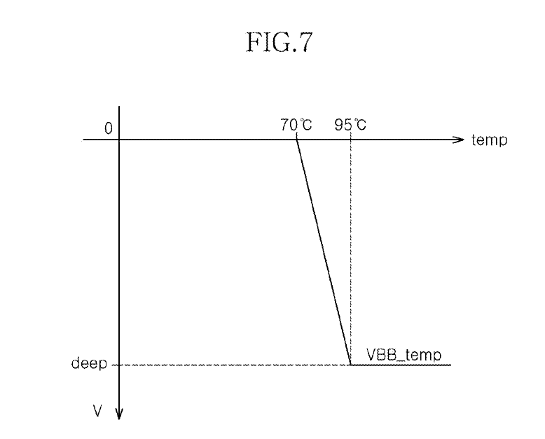

FIG. 7 is a graphical representation of exemplary voltage variation characteristics of another exemplary bulk bias voltage generator according to another embodiment. When comparing the voltage variation characteristics shown in FIGS. 5 and 7, FIG. 5 demonstrates that the absolute value of the bulk bias voltage (VBB_temp) can be linearly increased from a very low temperature to a high temperature. In contrast, FIG. 7 demonstrates that the absolute value of the bulk bias voltage (VBB_temp) can be rapidly reduced from a specific high temperature of more than about 70° C. after the bulk bias voltage (VBB_temp) is maintained at ground potential from a low temperature to the specific high temperature of about 70° C. Since the bulk bias voltage (VBB_temp) can be maintained at ground potential from a very low temperature to the specific temperature of about 70° C., the ground potential can be applied to the bulk of the NMOS transistor N1 of the power-up signal generating unit 410 when an ambient temperature is raised from the low very temperature to the specific temperature. Accordingly, the level of the power-up signal ‘Pwrup’ is not significantly varied.

When the ambient temperature is raised to more than the specific temperature, the low bulk bias voltage (VBB_temp) can be applied to the bulk of the NMOS transistor N1 of the power-up signal generating unit 410, so that the level variation of the power-up signal ‘Pwrup’ according to the temperature variation can be reduced. For example, the increment of the power-up signal ‘Pwrup’ according to the application of the bulk bias voltage can be more greatly increased as compared with the level reduction of the power-up signal ‘Pwrup’ according to the rise of temperature, so that the level variation of the power-up signal ‘Pwrup’ according to the temperature variation can be reduced in the power-up signal generator 1 equipped with the bulk bias voltage generator 420 having the temperature characteristics of FIG. 5.

While certain embodiments have been described above, it will be understood that the embodiments described are by way of example only. Accordingly, the device and method described herein should not be limited based on the described embodiments. Rather, the devices and methods described herein should only be limited in light of the claims that follow when taken in conjunction with the above description and accompanying drawings.

What is claimed is:

1. A power-up signal generator of a semiconductor memory apparatus, comprising:
a power-up signal generating unit that includes a MOS transistor having a gate receiving a divided voltage of an external supply voltage, the power-up signal generating unit determining a level of a power-up signal according to a turn-ON state of the MOS transistor; and
a bulk bias voltage generating unit that applies a bulk bias voltage to a bulk of the MOS transistor to adjust a threshold voltage of the MOS transistor,
wherein the bulk bias voltage varies according to a temperature of the semiconductor memory device.

2. The power-up signal generator of claim 1, wherein the MOS transistor includes an NMOS transistor.

3. The power-up signal generator of claim 1, wherein the bulk bias voltage generating unit reduces the bulk bias voltage when the temperature increases.

4. The power-up signal generator of claim 1, wherein the bulk bias voltage generating unit increases the bulk bias voltage when the temperature decreases.

5. The power-up signal generator of claim 2, wherein the bulk bias voltage generating unit reduces the bulk bias voltage when the temperature increases.

6. The power-up signal generator of claim 2, wherein the bulk bias voltage generating unit increases the bulk bias voltage when the temperature decreases.

7. The power-up signal generator of claim 1, wherein the bulk bias voltage generating unit supplies the bulk bias voltage having a constant level as long as the temperature is maintained in a predetermined level, and the bulk bias voltage generating unit supplies the reduced bulk bias voltage when the temperature exceeds the predetermined level.

8. The power-up signal generator of claim 2, wherein the bulk bias voltage generating unit supplies the bulk bias voltage having a constant level as long as the temperature is maintained in a predetermined level, and the bulk bias voltage generating unit supplies the reduced bulk bias voltage when the temperature exceeds the predetermined level.

9. A method for controlling a power-up signal generator of a semiconductor memory apparatus, comprising:
determining a level of a power-up signal from a power-up signal generator according to a turn-ON state of a MOS transistor of a power-up signal generating unit; and
applying a variable bulk bias voltage from a bulk bias voltage generating unit to a bulk of the MOS transistor to adjust a threshold voltage of the MOS transistor according to a temperature of the semiconductor memory device.

10. The method of claim 9, further comprising reducing the bulk bias voltage when the temperature increases.

11. The method of claim 9, further comprising increasing the bulk bias voltage when the temperature decreases.

12. The method of claim 9, wherein the bulk bias voltage generating unit supplies the bulk bias voltage having a constant level as long as the temperature is maintained in a predetermined level, and the bulk bias voltage generating unit supplies the reduced bulk bias voltage when the temperature exceeds the predetermined level.
